(19) United States
(12) Patent Application Publication
(10) Pub. No.: US 2025/0362416 A1
(43) Pub. Date: Nov. 27, 2025

(54) METHOD FOR MONITORING A KALMAN FILTER CALCULATION

(71) Applicant: Robert Bosch GmbH, Stuttgart (DE)

(72) Inventor: Simon Weissenmayer, Flein (DE)

(21) Appl. No.: 19/214,213

(22) Filed: May 21, 2025

(30) Foreign Application Priority Data
May 24, 2024 (DE) 10 2024 204 794.5

(51) Int. Cl. G01S 19/39; B60T 7/12

(52) U.S. Cl. CPC G01S 19/393; B60T 7/12

(57) ABSTRACT

A method for monitoring a Kalman filter calculation. A confidence interval is calculated using a Kalman filter, a value is predicted taking into account the confidence interval, the predicted value is compared with a measured value, an evaluation of the Kalman filter calculation is performed on the basis of a deviation ascertained during the comparison.

### FIELD

The present invention relates to a method for monitoring a Kalman filter calculation and to an arrangement for performing the method. The present invention also relates to a computer program and to a machine-readable storage medium.

### BACKGROUND INFORMATION

A Kalman filter, which serves to estimate system variables that cannot be directly measured, is a mathematical method for the iterative estimation of parameters, which in turn serve to describe system states.

The calculation of evidence, also known as marginal likelihood calculation, is used in multi-target tracking to compare the probability of different Kalman filter results with one another and to use the most likely result for functions based thereon.

It should be noted that Kalman filter model values should be secured so that interventions based on the result cannot lead to a reduction in braking force or to dangerous vehicle behavior. In particular, a velocity that was calculated too high should not lead to a reduction in braking force or to instability of the vehicle.

### SUMMARY

The present invention provides a method and an arrangement. Furthermore, the present invention provides a computer program, and a machine-readable storage medium. Example embodiments of the present invention can be found in the disclosure herein.

According to an example embodiment of the present invention, a method for monitoring a Kalman filter calculation is proved, in which a confidence interval is calculated by means of the Kalman filter, a value is predicted taking into account the confidence interval, the predicted value is compared with a measured value, and an evaluation of the Kalman filter calculation is performed on the basis of a deviation ascertained during the comparison.

The method presented is based on the following considerations:

The kernel of the marginal likelihood function:

$${L}_{pos} = \frac{1}{2} ( {\vec{y}}_{pos}^{T} {S}^{- 1} {\vec{y}}_{pos} )$$

With S=P+R, where P is the covariance matrix and R is the measurement covariance matrix of the Kalman filter, and where the positive difference \vec{y}ₚₒₛ between model values \vec{x} and measurement values \vec{z}

$${\vec{y}}_{pos} = \{ \begin{matrix}\vec{x} - \vec{z} for {x}_{vx} > {z}_{vx} \\ 0 for other\end{matrix}$$

with

$$\vec{x} = ( \begin{matrix}{x}_{vx} \\ {x}_{vy} \\ …\end{matrix} ) and \vec{z} = ( \begin{matrix}{z}_{vx} \\ {z}_{vy} \\ …\end{matrix} )$$

is calculated, the error sum E is added up with each time step whenever the positive difference y_{pos.vx} of the longitudinal velocity is greater than zero.

$$E = \{ \begin{matrix}{\sum }_{k} {L}_{pos , k} for {y}_{pos , vx , k} > 0 \\ 0 for other\end{matrix}$$

Here S stands for the residual covariance.

If the positive difference \vec{y}_{pos,vx} of the longitudinal velocity is calculated to be zero or less, the error sum is also set to zero. The error sum E exceeding a threshold Eₘₐₓ indicates that the longitudinal velocity may have been calculated too high and the approval for using the velocity to reduce the braking force of the vehicle in the anti-lock braking system (ABS) is withdrawn.

The approval can remain withdrawn until the vehicle is parked, even if the sum E falls below the threshold Eₘₐₓ again. This ensures that, in the case that the error sum E falls below the threshold Eₘₐₓ prematurely or does not exceed it in due time during subsequent braking, even though the modeled velocity is still too high or already too high again, this cannot lead to the braking force of the vehicle being reduced.

However, positive acceleration of the vehicle can also have the result that a positive difference \vec{y}ₚₒₛ is added up without this being caused by a faulty sensor or an erroneous calculation. For this reason, it may be advantageous to perform the summation only if the brake pedal is depressed so hard or a driving assistance system requests braking so great that the brake lights are switched on.

In addition to the measured longitudinal velocity zᵥₓ, further variables, such as lateral velocity, forces and accelerations acting on wheels, axles or the center of gravity of the vehicle, can be measured directly or indirectly and can thus be part of the vector \vec{z}. This also applies to the modeled longitudinal velocity xᵥₓ. If not all modeled variables xᵢ can be associated with a measurement variable zᵢ, an observation matrix Hₖ or an observation function Hₖ can be used to convert the model values \vec{x} into variables Hₖ\vec{x} that can be associated with the measurement values \vec{z}. In this case, the positive difference \vec{y}ₚₒₛ can be calculated according to

$${\vec{y}}_{pos} = \{ \begin{matrix}{H}_{k} \vec{x} - \vec{z} for {x}_{vx} > {z}_{vx} \\ 0 for other\end{matrix}$$

Certain model values and/or measurement values can have a large influence on the calculation of the kernel of the marginal likelihood function, although their influence has only a very small relationship with an erroneous longitudinal velocity. It may therefore be advantageous to exclude certain dimensions from the calculation. The kernel of the marginal likelihood function can also be calculated with only the one-dimensional longitudinal velocity difference y_{pos,vx} and the associated one-dimensional variance Sᵥₓ as

$${L}_{pos} = \frac{1}{2} ( \frac{{y}_{pos , vx}^{2}}{{S}_{vx}} )$$

Deviations between measurement values and corresponding model values influence one another. A deviation in the lateral velocity, for example, then also indirectly leads to a deviation in the longitudinal velocity, although a deviation in the longitudinal velocity due to a deviation in the lateral velocity often does not result in an overestimated velocity. It may therefore be advantageous to compensate for the influence of the other dimensions by weighting this influence with w and deducting it.

$${L}_{pos} = \frac{1}{2} ( \frac{{y}_{pos , vx}^{2}}{{S}_{vx}} ) - w \frac{1}{2} ( {\vec{y}}_{pos}^{T} {S}^{- 1} {\vec{y}}_{pos} )$$

Alternatively, in order to save computing time, the multiplication by ½ of the kernel of the marginal likelihood function can be dispensed with and the threshold Eₘₐₓ can instead be increased accordingly.

According to an example embodiment of the present invention, the above calculations are ideally performed with a second simplified Kalman filter, the model values of which are not used for further calculations, but which is optimized exclusively for error detection and is therefore particularly sensitive to the errors to be detected. If, for example, errors in a longitudinal acceleration sensor are to be secured, these errors can be detected particularly early with the second Kalman filter if the measurement noise is generally selected to be small in comparison to the first Kalman filter.

The Kalman filter model can also be used to model a lateral velocity x_{vy} or a sideslip angle x_{β}. In order to be able to use these variables for a stabilization intervention, the absolute modeled value must not be much larger than the absolute actual value. For this reason, the positive difference can particularly advantageously be calculated as

$${\vec{y}}_{pos} = \{ \begin{matrix}{H}_{k} \vec{x} - \vec{z} for {x}_{vx} > {z}_{vx} ⋁ \vert {x}_{vy} \vert > \vert {z}_{vy} \vert \\ 0 for other\end{matrix}$$

This also allows the lateral dynamic interventions to be secured by using the modeled variables to calculate stabilizing interventions only if the sum E does not exceed a threshold Eₘₐₓ. For an alternative use of a sideslip angle x_{β} instead of a lateral velocity x_{vy} in the model vector \vec{x}, z_{vy} can analogously be replaced by z_{β} in the measurement vector \vec{z}.

The modeled velocity can thus be secured against all sensor errors of the inertial sensors that lead to a longitudinal velocity that is incorrectly calculated too high.

Thus, in the method according to an example embodiment of the present invention, a counter or compensatory reaction is typically triggered when the ascertained deviation exceeds a threshold value. The compensatory reaction may consist in braking, even though, for example, locking has been detected.

The direction of the deviation, i.e., whether it is positive or negative, can also be taken into account. In this case, it is regularly defined in advance which of the possible directions is classified as critical.

Furthermore, according to an example embodiment of the present invention, a marginal likelihood calculation can be performed in order to compare the probability of different Kalman filter calculations with one another.

The presented arrangement of the present invention serves to monitor a Kalman filter calculation and has an evaluation unit configured to perform the method presented here. The arrangement can be implemented in hardware and/or software.

Further advantages and embodiments of the present invention can be found in the description herein and the figures.

Of course, the features mentioned above and those still to be explained below can be used not only in the respectively specified combinations but also in other combinations or alone, without departing from the scope of the present invention.

### BRIEF DESCRIPTION OF THE DRAWINGS

FIG. 1 shows curves of a longitudinal velocity and of a reference sensor in two graphs.

FIG. 2 shows curves, as in FIG. 1, in two graphs.

FIG. 3 shows curves corresponding to FIGS. 1 and 2 in two graphs.

FIG. 4 shows curves corresponding to FIGS. 1 to 3 in two graphs.

FIG. 5 shows curves corresponding to FIGS. 1 to 4 in one graph.

FIG. 6 shows curves corresponding to FIG. 5 in one graph.

FIG. 7 is a highly simplified, purely schematic representation of a vehicle with an arrangement for performing the method according to the present invention.

### DETAILED DESCRIPTION OF EXAMPLE EMBODIMENTS

The present invention is represented schematically in the figures on the basis of example embodiments and is described below in detail with reference to the figures.

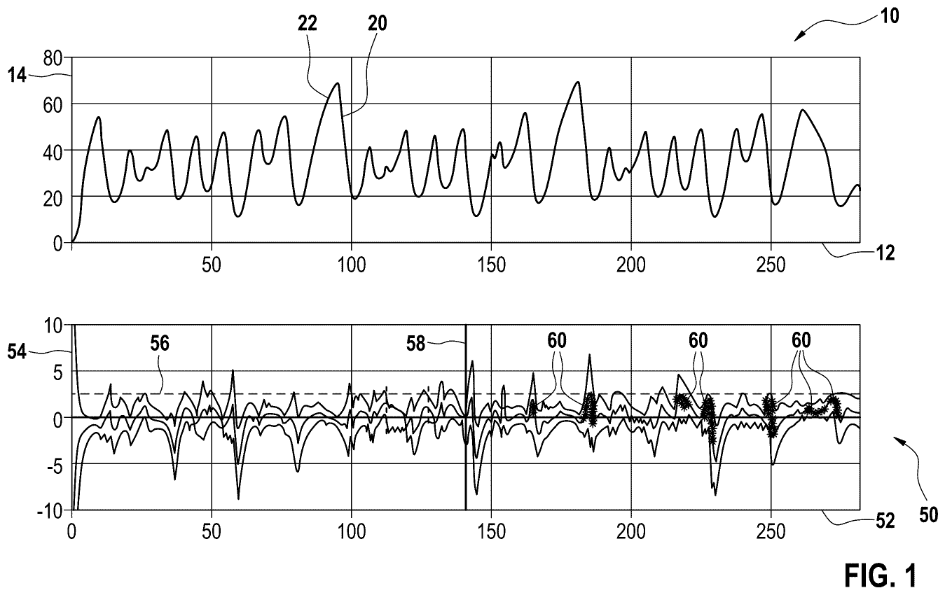

At the top, FIG. 1 shows a graph 10, with the time plotted on the abscissa 12 and the velocity plotted on the ordinate 14. The graph 10 shows the longitudinal velocity curves of a Kalman filter calculation 20 and of a reference sensor 22 in m/s over time in seconds of a vehicle on a race track. It should be noted that the two curves 20 and 22 are almost identical.

The lower diagram shows the slip error of the Kalman filter calculation calculated from the two velocity curves. The diagram shows a graph 50, with the time plotted on the abscissa 52 and the velocity plotted on the ordinate 54.

The two-sigma band is also plotted above and below the slip error. The horizontal lines 56 mark the maximum tolerable slip error of 2.5% during a braking process. No error detections (reference sign 60) occur up to the halfway point of the measurement (line 58). From the halfway point of the measurement, the measurement value of the longitudinal acceleration sensor was reduced by 2%. This leads to necessary optional error detections (reference sign 60), wherein the resulting slip error does not exceed the 2.5% line 56. Undetected slip errors greater than 2.5% do not occur.

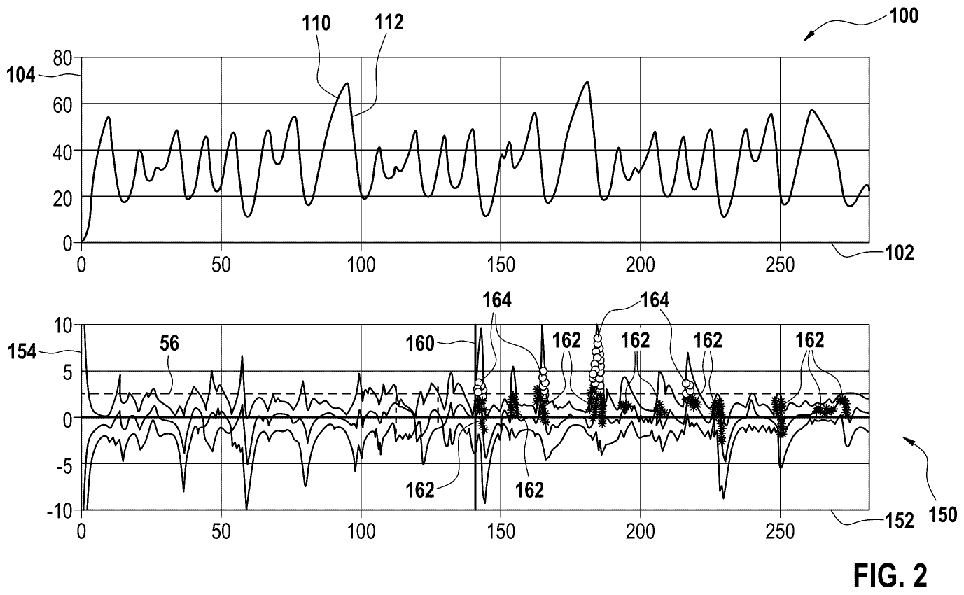

At the top, FIG. 2 shows a graph 100, with the time plotted on the abscissa 102 and the velocity plotted on the ordinate 104. The graph 100 shows the longitudinal velocity curves of a Kalman filter calculation 110 and of a reference sensor 112 in m/s over time in seconds of a vehicle on a race track. It should be noted that the two curves 110 and 112 are almost identical.

The lower diagram shows the slip error of the Kalman filter calculation calculated from the two velocity curves. The diagram shows a graph 150, with the time plotted on the abscissa 152 and the velocity plotted on the ordinate 154.

From the halfway point of the measurement (line 160), the measurement value of the longitudinal acceleration sensor was reduced by 5%. In addition to the optional error detections (reference sign 162), this also leads to necessary error detections (reference sign 164) where the resulting slip error is greater than 2.5%.

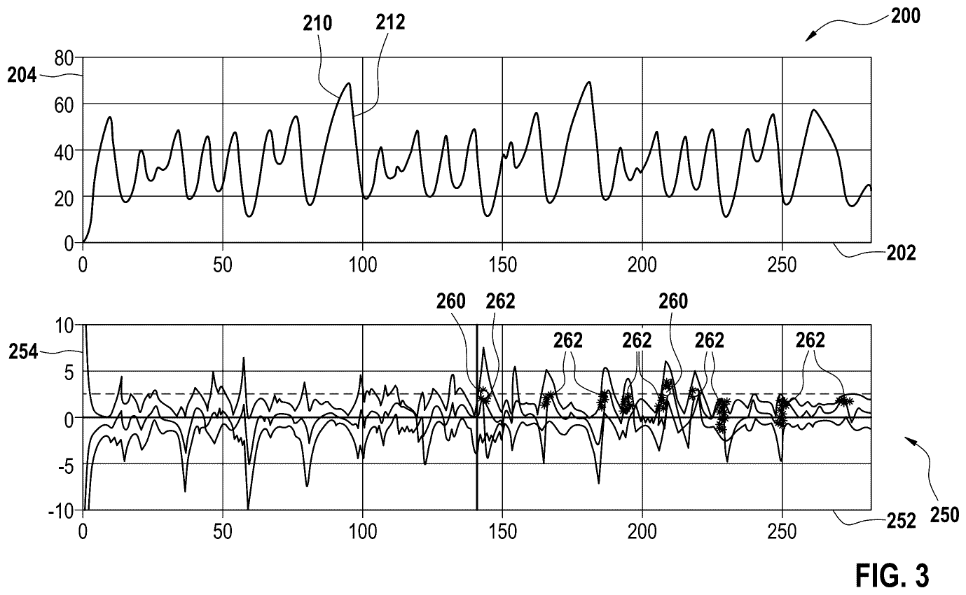

At the top, FIG. 3 shows a graph 200, with the time plotted on the abscissa 202 and the velocity plotted on the ordinate 204. The graph 200 shows the longitudinal velocity curves of a Kalman filter calculation 210 and of a reference sensor 212 in m/s over time in seconds of a vehicle on a race track. It should be noted that the two curves 210 and 212 are almost identical.

The lower diagram shows the slip error of the Kalman filter calculation calculated from the two velocity curves. The diagram shows a graph 250, with the time plotted on the abscissa 252 and the velocity plotted on the ordinate 254.

The graph 250 shows that doubling the measurement value of the lateral acceleration also leads to errors in the longitudinal acceleration of more than 2.5%, which are detected (reference sign 260). Optional error detections are denoted by reference sign 262.

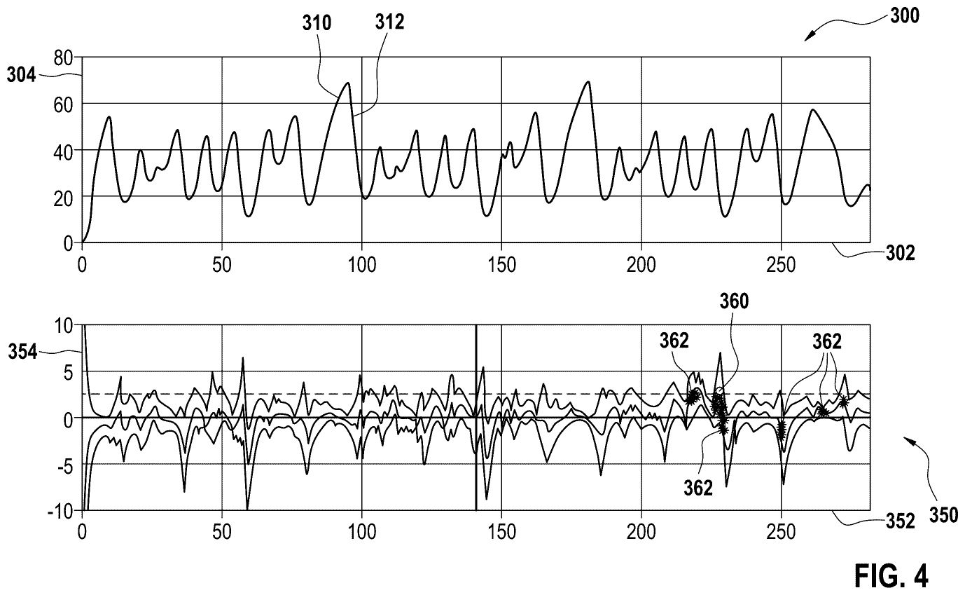

At the top, FIG. 4 shows a graph 300, with the time plotted on the abscissa 302 and the velocity plotted on the ordinate 304. The graph 300 shows the longitudinal velocity curves of a Kalman filter calculation 310 and of a reference sensor 312 in m/s over time in seconds of a vehicle on a race track. It should be noted that the two curves 310 and 312 are almost identical.

The lower diagram shows the slip error of the Kalman filter calculation calculated from the two velocity curves. The diagram shows a graph 350, with the time plotted on the abscissa 352 and the velocity plotted on the ordinate 354.

FIG. 4 shows that even a reduction of the measurement value of the roll rate by 30% can lead to detected slip errors greater than 2.5% (reference sign 360). Optional error detections are denoted by reference sign 362.

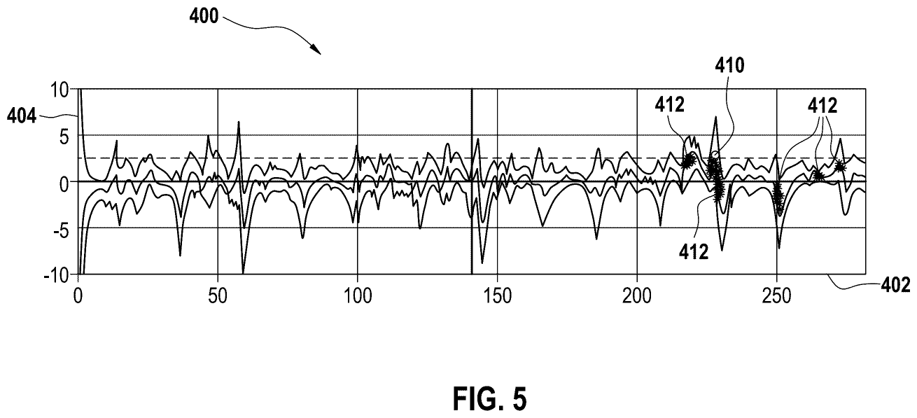

FIG. 5 shows a graph 400, with the time plotted on the abscissa 402 and the velocity plotted on the ordinate 404. The graph 400 shows that an increase in the measurement value of the pitch rate by just 25% can lead to detected slip errors (reference sign 410) greater than 2.5%. Optional error detections are denoted by reference sign 412.

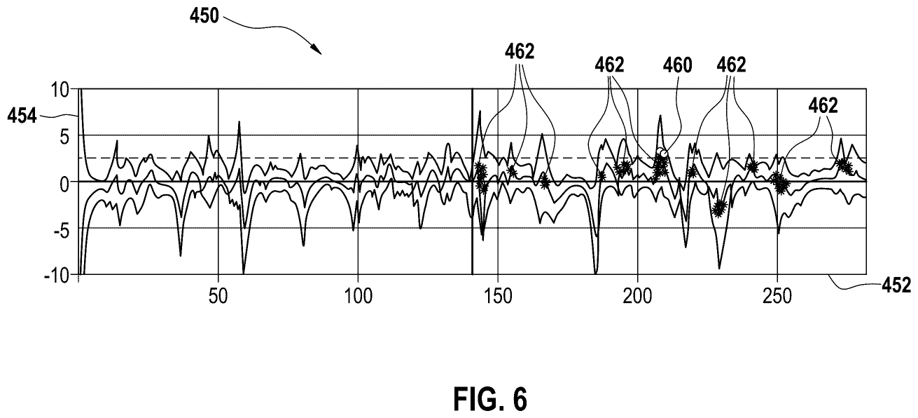

FIG. 6 shows a graph 450, with the time plotted on the abscissa 452 and the velocity plotted on the ordinate 454. The graph 450 shows that halving the measurement value of the yaw rate can also lead to detected slip errors (reference sign 460) greater than 2.5%. Optional error detections are denoted by reference sign 462.

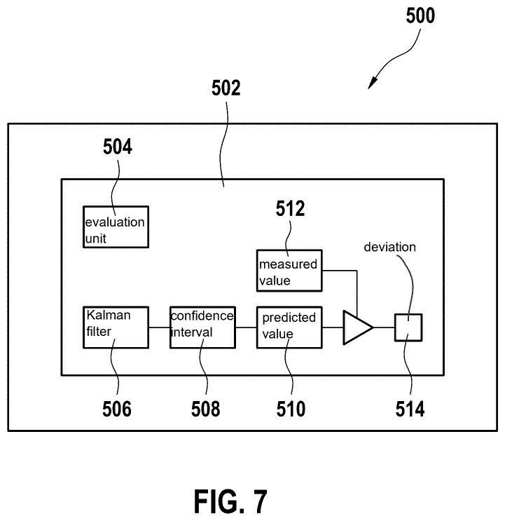

The calculations were performed based on real vehicle measurements. An extended Kalman filter was chosen as the Kalman filter, wherein the inertial measurement values have been incorporated directly into the model equations and only the correction of the longitudinal and lateral velocities on the basis of speed sensors and steering angle sensors has been incorporated as usual via the correction equations \vec{z}. The longitudinal and lateral velocities as well as the roll and pitch angles were selected as conditions \vec{x} for the Kalman filter. FIG. 7 shows a highly simplified and purely schematic representation of a vehicle, which is denoted as a whole by reference sign 500. In the vehicle 500, an arrangement 502 for performing the method is provided, in which an evaluation unit 504 is provided. Furthermore, a Kalman filter 506 is available, which calculates a confidence interval 508. Taking into account this confidence interval 508, a value 510 is predicted, which in turn is compared with a measured value 512. This results in a deviation 514, which is used to evaluate the calculation of the Kalman filter 506. A computing unit is typically provided in the evaluation unit 502.

In principle, the presented method can be used in all ESP and GNSS control units.

1. Method for monitoring a Kalman filter calculation, in which
a confidence interval (508) is calculated by means of a Kalman filter (506),
a value (510) is predicted taking into account the confidence interval (508),
the predicted value (510) is compared with a measured value (512),
an evaluation of the Kalman filter calculation is performed on the basis of a deviation (514) ascertained during the comparison.

2. Method according to claim 1, in which a compensatory reaction is triggered if the deviation (514) exceeds a threshold value.

3. Method according to claim 2, in which the compensatory reaction consists in braking.

4. Method according to one of claims 1 to 3, in which a direction of the deviation (514) is taken into account.

5. Method according to claim 4, in which it is defined in advance which of the possible directions is classified as critical.

6. Method according to one of claims 1 to 5, in which a marginal likelihood calculation is performed in order to compare the probability of different Kalman filter calculations with one another.

7. Arrangement for monitoring a Kalman filter calculation with an evaluation unit (502), which is configured to perform a method according to one of claims 1 to 6.

8. Computer program having program code means, which computer program is configured to perform a method according to one of claims 1 to 6 when the computer program is executed on a computing unit, in particular a computing unit in an arrangement (502) according to claim 7.

9. Machine-readable storage medium having a computer program according to claim 8 stored thereon.
